(19) United States
(12) Patent Application Publication
(10) Pub. No.: US 2016/0035633 A1
(43) Pub. Date: Feb. 4, 2016

(54) LOW ENERGY COLLIMATED ION MILLING OF SEMICONDUCTOR STRUCTURES

(71) Applicant: International Business Machines Corporation, Armonk, NY (US)

(72) Inventor: TERENCE L. KANE, WAPPINGERS FALLS, NY (US)

(21) Appl. No.: 14/882,804

(22) Filed: Oct. 14, 2015

Related U.S. Application Data
(62) Division of application No. 13/851,148, filed on Mar. 27, 2013.

(51) Int. Cl. H01L 21/66; H01L 21/302

(52) U.S. Cl. CPC H01L 22/12; H01L 21/302; H01L 22/26; H01L 22/14

(57) ABSTRACT

A method of delayering a surface of a semiconductor structure may include applying a voltage in the range of about 50 eV to less than 300 eV to an inductively coupled Argon ion source operating at a radio frequency. A collimated ion beam incident on the surface of the semiconductor structure may be generated, from the Argon ion source, for the planar removal of layers of the surface. A structural material underlying the surface of the semiconductor structure is exposed using an end-point detector based on the planar removal of the layers.

### BACKGROUND

The present invention generally relates to semiconductor device testing, and more particularly, to the delayering of semiconductor devices for facilitating such testing.

Semiconductor device performance may be measured using a myriad of techniques and instruments. For example, in order to perform Atomic Force Probing (AFP) of a semiconductor device or structure, various layers may need to be removed for exposing the device or structure's contacts (e.g., tungsten studs) or surface prior to probing. Such layer removal or delayering may be carried out using either more coarse methods such as chemical mechanical polishing (CMP) or relatively high-precision techniques employing, for example, focused or collimated high-energy (>500 eV) ion beam etching. Such delayering techniques may, however, damage the device or structure's surface, or alternatively, introduce unwanted irregularities (e.g., unwanted ion implantation) into the device or structure. For example, the process used to prepare the device or structure prior to test or evaluation may undesirably introduce defects (e.g., gallium ion implantations due to high energy ion beam etching) or produce shifts in performance characteristics (e.g., MOSFET threshold voltage (Vₜ) shifts). This may subsequently be misconstrued as a device characteristic resulting from fabrication processes as opposed to a measurement induced defect.

It may, therefore, be desirable, among other things, to perform delayering processes while maintaining the structural and characteristic integrity of the device or structure under test.

### BRIEF SUMMARY

According to at least one exemplary embodiment, a method of delayering a surface of a semiconductor structure may include applying a voltage in the range of about 50 to less than 300 eV to an inductively coupled Argon ion source operating at a radio frequency. A collimated ion beam incident on the surface of the semiconductor structure is generated, from the Argon ion source, for the planar removal of layers of the surface, whereby a structural material underlying the surface of the semiconductor structure is exposed using an end-point detector based on the planar removal of the layers.

According to at least one other exemplary embodiment, a method of delayering a surface of a semiconductor structure may include applying a voltage in the range of about 50 to less than 300 eV to an inductively coupled Argon ion source operating at a radio frequency and generating, from the Argon ion source, a collimated ion beam incident on a crystalline surface of the semiconductor structure for planar removal of layers of the crystalline surface. The collimated ion beam minimizes surface amorphization of the crystalline surface of the semiconductor structure and exposes a structural material underlying the crystalline surface of the semiconductor structure using an end-point detector based on the planar removal of the layers.

According to at least one other exemplary embodiment, a method of delayering a surface of a three-dimensional semiconductor structure may include applying a voltage in the range of about 50 to less than 300 eV to an inductively coupled Argon ion source, applying a 1.4 MHz or approximately 1.4 MHz radio signal to the inductively coupled Argon ion source, and generating, from the Argon ion source, a collimated ion beam incident on a crystalline surface of the three-dimensional semiconductor structure for planar removal of layers of the crystalline surface. The collimated ion beam minimizes surface amorphization of the crystalline surface of the three-dimensional semiconductor structure and exposes a structural material underlying the crystalline surface of the three-dimensional semiconductor structure using an end-point detector based on the planar removal of the layers.

### BRIEF DESCRIPTION OF THE SEVERAL VIEWS OF THE DRAWINGS

FIG. 1 is a system diagram of an ion beam milling apparatus according to an exemplary embodiment;

FIG. 2 is a process flow diagram corresponding to a testing process associated with a semiconductor structure according to an exemplary embodiment; and

FIG. 3 is flow diagram corresponding to configuring the ion beam milling apparatus of FIG. 1 according to an exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

The following one or more exemplary embodiments describe a low energy ion beam milling apparatus and method utilized for the purpose of delayering the surfaces of semiconductor devices for subsequent testing and characterization of such devices. The delayering of various surfaces of semiconductor devices, particularly three-dimensional semiconductor devices such as FinFet transistor devices, may inadvertently introduce defects and unwanted artifacts within the devices. For example, a high-energy 500 eV focused gallium ion beam may, during the milling and delayering process of a FET device, cause a shift in the threshold voltage (Vₜ) of the FET device. Additionally, the high-energy ion beam may alter dopant density or dopant distribution. In all such cases, the device may be characterized incorrectly as a result of the induced irregularities or defects that are inadvertently introduced into the semiconductor device under tests based on the ion beam milling process.

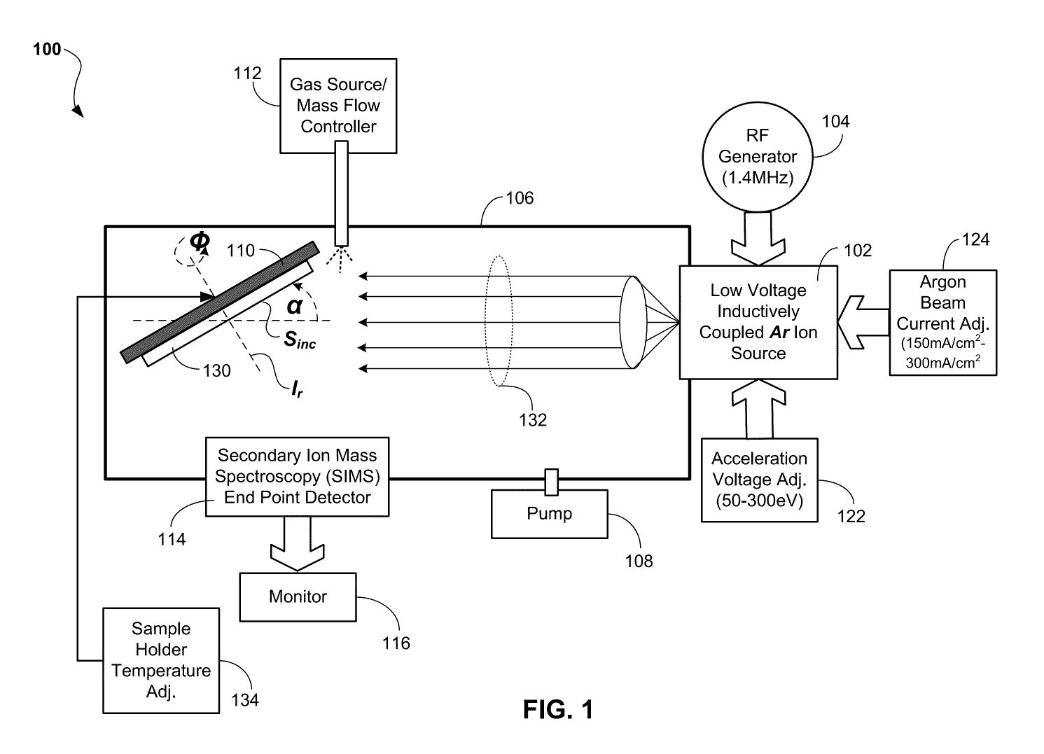

Referring to FIG. 1, a system diagram of an ion beam milling apparatus 100 according to an exemplary embodiment is depicted. The ion beam milling apparatus 100 may include a low voltage inductively coupled Argon (Ar) ion source 102, an RF signal source 104, a chamber 106 (e.g., stainless steel), a pump 108, a semiconductor device holder 110, a gas source/mass flow controller 112, a secondary ion mass spectroscopy (SIMS) end point detector 114, and an optional monitor 116 coupled to the SIMS detector 114.

As illustrated, a radio frequency (RF) signal source 104 generates a 1.4 MHz RF signal that is applied to the low voltage inductively coupled Argon (Ar) ion source 102. The low voltage inductively coupled Argon (Ar) ion source 102 also includes a means for adjusting the acceleration voltage 122 of the low voltage inductively coupled Argon (Ar) ion source 102 and a means for adjusting the Ar beam current 124 of the low voltage inductively coupled Argon (Ar) ion source 102.

The semiconductor device holder 110 may hold a semiconductor device under test (DUT) 130. The device holder 110 may accordingly have an adjustable angular orientation (α) relative to an incident collimated ion beam 132 generated by the low voltage inductively coupled Argon (Ar) ion source 102. In addition to the angular orientation (α), the semiconductor device holder 110 also rotates about its own axis, as denoted by Iᵣ, at an adjustable rotational speed (φ). The semiconductor device holder 110 may also include a means for adjusting its temperature 134.

In operation, the low voltage inductively coupled Argon (Ar) ion source 102 generates an inert low-energy collimated Ar ion beam 132 that is incident upon the DUT 130 that is placed and secured in the device holder 110. As shown in FIG. 1, the inert low-energy collimated ion beam 132 is incident upon DUT 130 at angular orientation α. As the inert low-energy collimated ion beam 132 mills and, therefore, delayers incident surface S_{inc} of the DUT 130, secondary ions generated at the surface S_{inc} being etched are detected by the SIMS detector 114. The generated secondary ions may, for example, have characteristics such as mass-to-charge ratio which may differ based on the different layers of material that may be encountered during the milling operation. This distinction in characteristics may be used in order to provide a precise determination of the layer being milled. Using, for example, pulse counting, the SIMS detector 114 may generate a SIMS trace of counts per second (i.e., cis) over time (i.e., t) for the detected secondary ions generated during the ion milling. These traces may be displayed graphically on monitor 116. Other diagnostic tools such as Fast Fourier Transform (FFT) analysis may be included with the SIMS detection process.

Based on the DUT 130 and the material that is to be delayered by the ion beam milling apparatus 100, different operating regimes may be employed by, for example, adjusting the acceleration voltage via adjustment means 122, adjusting the Ar beam current via adjustment means 124, adjusting the device holder 110 temperature via adjustment means 134, adjusting the chamber 106 pressure via pump 108, setting the angular orientation (α) and rotational speed (φ) of the device holder 110, applying an RF signal to the low voltage inductively coupled Argon (Ar) ion source 102, and the application (optionally) of etch selective gases via the gas source/mass flow controller 112. For example, etch selective hexafluoroethane (C₂F₆) gas may be used for removing silicon nitride hardmask materials and etch selective tetrafluoromethane (CF₄) gas may be used for removing silicon oxide. In the context of ion beam milling and Atomic Force Probing (AFP), both silicon oxide and silicon nitride layers may cause damage to the probes used in the AFP process. Thus, these layers are removed prior to AFP.

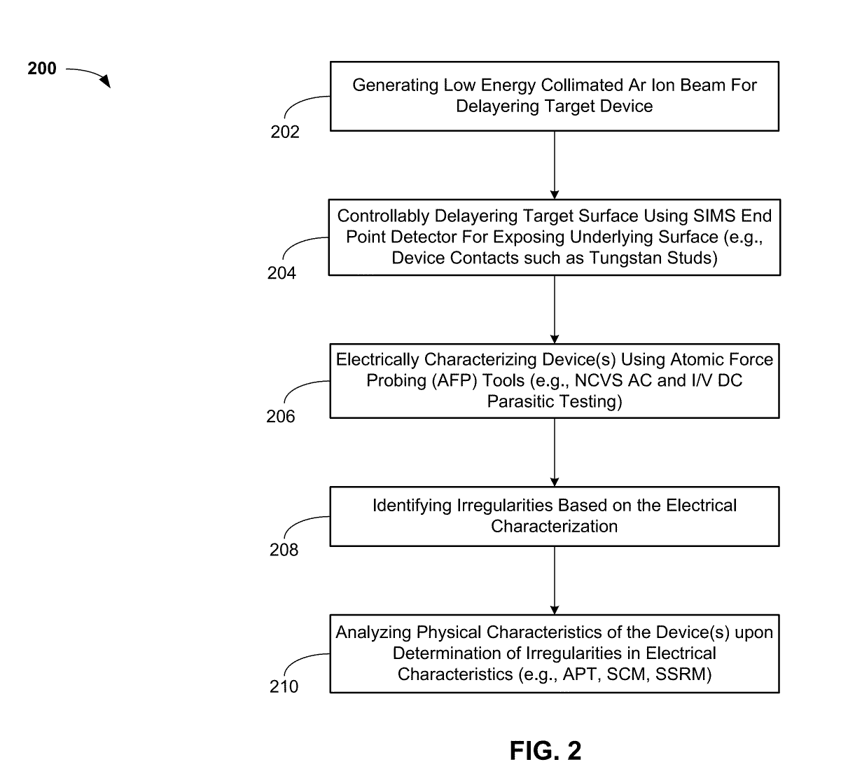

FIG. 2 is a process flow diagram 200 corresponding to a testing process associated with a semiconductor structure according to an exemplary embodiment. At 202, a low-energy collimated inert Ar ion beam may be generated by an apparatus, such as apparatus 100 (FIG. 1), for delayering a target device under test (DUT).

At 204, based on the generated low-energy collimated inert Ar ion beam (202), a controlled delayering of the target surface of the DUT is accomplished using, for example, a SIMS endpoint detector such as SIMS detector 114 (FIG. 1). For example, layers of copper my be removed by the generated low-energy collimated inert Ar ion beam in order to expose the tungsten studs corresponding to a Field Effect Transistor (FET) selected for characterization testing. Once exposed, using AFP, the tungsten studs may be probed for characterizing the FET device. Alternative examples may include delayering silicon nitride or silicon oxide layers that have been deposited on three-dimensional (3D) semiconductor structures such the Fins of FinFET type devices. In this example, the 3D structure may be especially susceptible to the impact of a high-energy ion beam milling process. For example, the electrical probing (e.g., Atomic Force Probing) of a Fin structure may require the removal of a silicon nitride hard mask (i.e., with etch selective hexafluoroethane gas—C₂F₆) located on the top surface of the Fin. Since the Fin may have a thickness dimension in the region 10-15 nm, an incident high-energy ion beam (e.g., >500 eV) may cause amorphization damage to the Fin, which in turn may be reflected in the subsequently obtained characterization results (e.g., current-voltage I/V curves, APT measurements, SSRM measurements, SCM measurements, etc.) associated with the device (i.e., FinFET device).

At 206, once the desired area or surface of the DUT is exposed (204), the device may be electrically characterized using Atomic Force Probing (AFP) tools such as, but not limited to, Nanoprobe Capacitance-Voltage Spectroscopy (NCVS) AC based parasitic testing and Current-Voltage (UV) DC based parasitic testing.

At 208, any irregularities or characteristic defects in the DUT may be identified based on an evaluation of the results of the electrical characterization obtained during the AFP process (206). Based on the detection of such irregularities or defects (208), at 210, the physical characteristic of the DUT are further evaluated using, for example, Atomic Probe Tomography (APT), Scanning Capacitance Microscopy (SCM), and/or Scanning Spreading Resistance Microscopy (SSRM). AFT may be utilized to determined doping concentration, while SSRM techniques may be indicative of dopant distribution associated with the DUT. SCM may be used to evaluate carrier density.

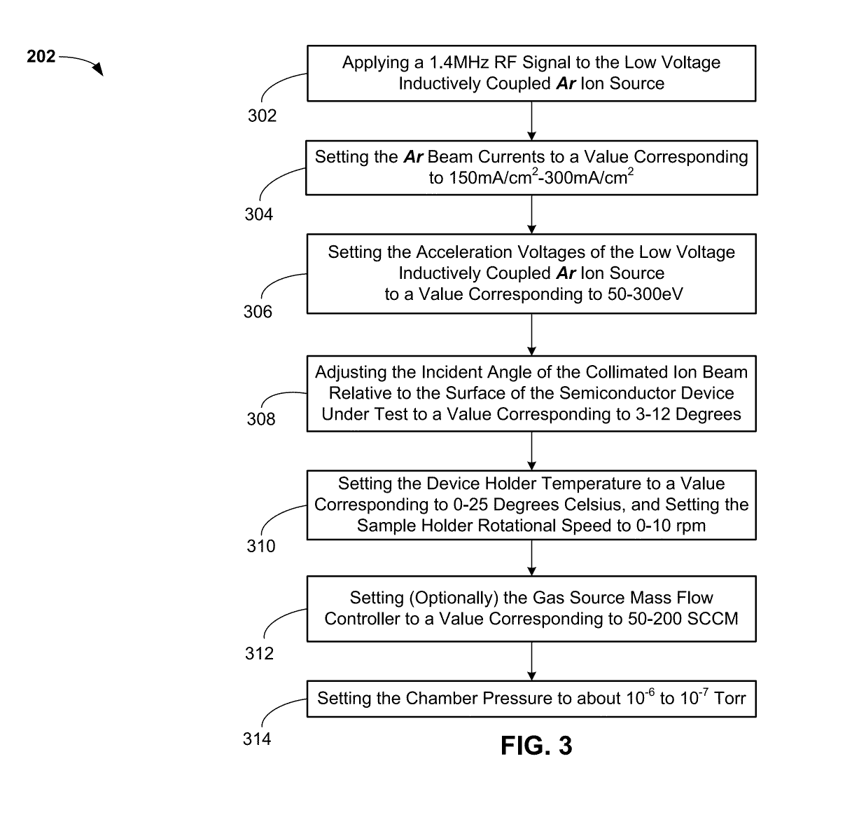

FIG. 3 is flow diagram 202 corresponding to configuring the ion beam milling apparatus of FIG. 1 according to an exemplary embodiment. The following settings allow the generation of a collimated low-energy (<300 eV) inert Ar ion beam that provides delayering without altering the characteristics of the device under test (DUT). The settings include a range of values based on the DUT and the material that is being delayered. The flow diagram 202 of FIG. 3 is described with the aid of FIG. 1.

At 302, a radio frequency signal of 1.4 MHz or approximately 1.4 Mhz is applied to the low voltage inductively coupled Argon (Ar) ion source 102. The Ar Beam current may be set to a value between 150 mA/cm²-300 mA/cm² (304). The acceleration voltage of the low voltage inductively coupled Argon (Ar) ion source 102 may be set to a value of about 50 eV to a value less than 300 eV (306).

At 308, the incident angle a between the incident collimated Ar beam 132 and the surface S_{inc} of the DUT 130 that is held by semiconductor device holder 110 within the stainless steel chamber 106 may be adjusted to be around 3-12 degrees. Greater or lesser angles may also be contemplated.

At 310, the device holder 110 temperature may be adjusted to be about 0-25 degrees Celsius, while the device holder 110 rotational speed (φ) may be varied to be between about 0-10 revolutions per minute (rpm). At 312, depending on the material that is being delayered, etching gas (e.g., C₂F₆, CF₄) may be applied within the chamber 106 at a flow rate of between 50 to about 200 standard cubic centimeters per minute (SCCM). For example, in some instances etching gases may not be utilized. One example of not using an etch-selective gas may be during the delayering of copper material for exposing tungsten studs prior to the AFP process. At step 314, the chamber pressure may be set to be about 10⁻⁶ to about 10⁻⁷ Torr, although lesser or greater pressures may also be contemplated.

It may be appreciated that the various processes of FIG. 3 may be carried out in no particular order prior to delayering the DUT 130. As previously mentioned, the various adjustment parameters described in relation to FIG. 3 may be set and, in some instances, readjusted based on DUT type (e.g., 3D devices such as FinFETs) and/or the material on the DUT being delayered (e.g., copper, silicon nitride, etc.).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A method of delayering a surface of a semiconductor structure, comprising:
applying a voltage in the range of about 50 eV to less than 300 eV to an inductively coupled Argon ion source operating at a radio frequency;
generating, from the Argon ion source, a collimated ion beam incident on the surface of the semiconductor structure for planar removal of layers of the surface;
exposing a structural material underlying the surface of the semiconductor structure using an end-point detector based on the planar removal of the layers,
wherein the exposed structural material underlying the surface of the semiconductor structure comprises tungsten studs coupled to a semiconductor device under test (DUT).

2. The method of claim 1, further comprising:
applying atomic force probing to the tungsten studs coupled to the semiconductor device under test; and
determining irregularities in the device under test based on the atomic force probing.

3. The method of claim 2, wherein the determining of the irregularities in the device under test based on the atomic force probing comprises:
performing nanoprobe capacitance voltage spectroscopy (NCVS) on the device under test.

4. The method of claim 3, wherein the determining of the irregularities in the device under test based on the atomic force probing comprises:
determining current-voltage (I-V) characteristics of the device under test; and
determining capacitance-voltage (C-V) characteristics of the device under test.

5. The method of claim 4, further comprising:
determining doping concentration in the device under test using atomic probe tomography (APT).

6. The method of claim 5, further comprising:
determining carrier density in the device under test using scanning capacitance microscopy (SCM).

7. The method of claim 6, further comprising:
determining dopant distribution in the device under test using scanning spreading resistance microscopy (SSRM), wherein the collimated ion beam incident on the surface of the semiconductor structure for planar removal of layers of the surface mitigates the introduction of defects into the device under test.
